(19) United States
(12) Patent Application Publication
(10) Pub. No.: US 2006/0145206 A1
(43) Pub. Date: Jul. 6, 2006

(54) CMOS image sensor and method for fabricating the same

(76) Inventor: Seung Hyun Kim, Pocheon-city (KR)

Correspondence Address: MCKENNA LONG & ALDRIDGE LLP, 1900 K STREET, NW, WASHINGTON, DC, 20006, US

(21) Appl. No.: 11/314,346

(22) Filed: Dec. 22, 2005

(30) Foreign Application Priority Data
Dec. 30, 2004 (KR) P 2004-0116420

(51) Int. Cl. H01L 31/113

(52) U.S. Cl. 257/292

(57) ABSTRACT

A CMOS image sensor having a transistor and a method for fabricating the same is provided. The CMOS image sensor includes a semiconductor substrate; a gate electrode of the transistor formed on the semiconductor substrate; and an ion-implantation blocking layer formed as part of the gate electrode. The CMOS image sensor prevents a channel region below the gate electrode from being doped with impurity ions.

This application claims the benefit of Korean Patent Application No. 10-2004-0116420, filed on Dec. 30, 2004, which is hereby incorporated by reference for all purposes as if fully set forth herein.

### BACKGROUND OF THE INVENTION

1. Field of the Invention

The present invention relates to complementary metal-oxide-semiconductor (CMOS) image sensors and more particularly, to a CMOS image sensor having a transistor and a method for fabricating the same. The CMOS image sensor employs an ion-implantation blocking layer formed in a gate electrode of the transistor to prevent a channel region below the gate electrode from being doped with impurity ions.

2. Discussion of the Related Art

An image sensor is a semiconductor device which transforms an optical image into an electrical image and may be a charge-coupled device or a CMOS image sensor.

In a charge-coupled device, a multitude of individual metal-oxide-silicon (MOS) capacitors, each of which can store and convey a charge carrier, are arranged in very close proximity to one another. Charge-coupled devices have drawbacks, including a complicated driving manner, high electric power consumption, and a complicated expensive manufacturing process resulting from many mask processes. It is difficult to manufacture a single-chip charge-coupled device due to the impediment of devising a signal processing circuit that can be implemented in such a chip.

CMOS image sensors, on the other hand, are devices which have MOS transistors that correspond to pixels and use a control circuit and a signal processing circuit as a peripheral circuit. MOS transistors are formed by CMOS technology. CMOS image sensors adopt switching technology which allows outputs to be sequentially detected through the MOS transistors corresponding to the number of pixels. The pixels are arrayed on a semiconductor or silicon substrate. Thus, the CMOS image sensor comprises signal processing chips including photodiodes. Each signal processing chip is provided with an amplifier, an analog-to-digital converter, a voltage regulator, a timing generator, and digital logic circuitry. As such, the CMOS image sensor realizes smaller layouts and overall size, reduced power consumption, and less cost.

There are several different types of pixel structures for CMOS image sensors. Representatively commercialized types include a pixel unit of a three-transistor (3-T) structure comprising three basic transistors and one photo-sensing means (e.g., a photodiode) and a pixel unit of a four-transistor (4-T) structure comprising four basic transistors and one photo-sensing means. A 3-T CMOS image sensor of the related art is shown in FIG. 1, in which a unit pixel comprises a photo-sensor 8 for receiving an optical signal and generating electrical charges accordingly, a reset transistor 9 for resetting the charges generated in the photo-sensor, a drive transistor 10 functioning as a source-follower buffer amplifier, and a select transistor 11 for performing addressing operations. Similarly, a 4-T CMOS image sensor of the related art is shown in FIG. 2, in which a unit pixel comprises a photo-sensor 12 for receiving an optical signal and generating electrical charges accordingly, a transfer transistor 13 for transferring charges accumulated in the photo-sensor, a reset transistor 14 for resetting the charges generated in the photo-sensor, a drive transistor 15 functioning as a source-follower buffer amplifier, and a select transistor 16 for performing addressing operations.

The photosensitivity of the CMOS image sensor can be increased by increasing the levels of light reaching the photo-sensing means, i.e., the photo-sensor 8 or 12. In either case, electrons are generated according to the amount of incident light passing through a microlens (not shown) and accumulate in the photo-sensing means. The accumulation of electrons in the photo-sensing means causes a voltage change in the drive transistor 10 or 15; thus, the operation of the CMOS image sensor is a result of the accumulation of electrons.

FIG. 3 is a cross-section taken along the line A-A′ of the reset transistor 9 of FIG. 1 or a cross-section taken along the line B-B′ of the transfer transistor 13 of FIG. 2. Referring to FIG. 3, reset transistor 9 or transfer transistor 13 is formed in a semiconductor substrate 1, which is heavily doped with P-type impurity ions. Reset transistor 9 or transfer transistor 13 each include a P-type epitaxial layer 2 formed on the semiconductor substrate 1, a shallow-trench isolation region 7, an N⁻ region 6 formed as a diffusion area in a predetermined surface region of the epitaxial layer 2, a gate oxide layer 5, and a gate electrode 4 of polysilicon sequentially formed on the epitaxial layer 2 to be disposed adjacent the N⁻ region 6. After patterning to form the gate oxide layer 5 and gate electrode 4, spacers 3 are formed on the gate sidewalls. The shallow-trench isolation region 7, which provides isolation between fields, is essentially a trench filled with an insulating material. The N⁻ region 6 is formed by lightly doping the P-type epitaxial layer 2 with impurities, using the gate electrode 4 as a mask, and serves as a source region of the reset transistor 9 or the transfer transistor 13.

When a reverse bias is applied between the N⁻ region 6 and the P-type epitaxial layer 2, a depletion layer is formed over a large area, i.e., the photo-sensing area. An increase in the size of the depletion layer to form a larger depletion layer directly improves the photosensitivity of the CMOS image sensor. A larger depletion layer can be realized by implanting ions to the epitaxial layer 2 at higher energy levels using an ion-implantation mask, whereby the N⁻ region 6 is formed more deeply.

FIG. 4 illustrates a process step for fabricating the CMOS image sensor of FIG. 1 or FIG. 2. A photoresist pattern 17 is used, in conjunction with the gate electrode 4, as the ion-implantation mask for the formation of the N⁻ region 6. It should be noted that processing tolerances in the formation and alignment of the ion-implantation mask will normally expose some portion of the polysilicon gate electrode 4. Then, if ions are implanted at high energy, the implanted ions penetrate the exposed portion of the gate electrode 4 to become implanted in a corresponding portion of the epitaxial layer 2 below the gate electrode 4. Therefore, the thus-formed N^{'1} region 6 partially extends to a channel region under the gate electrode 4. The channel region cannot completely block the ion implantation, especially at higher energy levels.

Meanwhile, a silicide layer (not shown) is typically deposited on a patterned polysilicon layer forming the gate electrode 4. Before forming the silicide layer, however, the upper side of the gate electrode 4 should undergo a preparation step, namely, the formation of an amorphous site on a contact surface of the gate electrode 4.

The above-described presence of the N⁻ region 6 in an area of the epitaxial layer 2 below the gate electrode 4 causes excessively high levels of leakage current to be generated when operating the image sensor, thereby deteriorating the picture quality of the image sensor. Moreover, the alignment or position of the photoresist pattern 17 varies according to processing conditions, resulting in inconsistent and unpredictable levels of the leakage current. Thus, the exact position of the N⁻ region 6 varies, such that yield inevitably suffers. To guard against improperly forming the N⁻ region as described above and to increase yield, the formation of the ion-implantation mask must be carefully controlled. However, this increases fabrication costs.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is to provide a CMOS image sensor and a method for fabricating the same, in which an amorphous silicon layer is formed as part of a polysilicon gate electrode in a reset transistor or a transfer transistor, to prevent the formation of a deep N⁻ region in a channel region below the gate electrode.

Another advantage of the present invention is to provide a CMOS image sensor and a method for fabricating the same, which enables a reduction in a leakage current.

Another advantage of the present invention is to provide a CMOS image sensor and a method for fabricating the same, which facilitates an ion-implantation step for forming a deep N⁻ region serving as a source region in a reset transistor or a transfer transistor.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages and in accordance with the purpose of the present invention, as embodied and broadly described herein, there is provided a CMOS image sensor having a transistor. The CMOS image sensor comprises a semiconductor substrate; a gate electrode of the transistor formed on the semiconductor substrate; and an ion-implantation blocking layer formed as part of the gate electrode.

In another aspect of the present invention, there is provided a method for fabricating a CMOS image sensor having a transistor. The method comprises forming a shallow-trench isolation region in a semiconductor substrate of a first conductive type; forming a gate electrode on the semiconductor substrate; forming an ion-implantation blocking layer as part of the gate electrode; and performing an ion-implantation step to form a diffusion area of a second conductive type in the semiconductor substrate adjacent the gate electrode.

In another aspect of the present invention, there is provided a method for fabricating a CMOS image sensor having a transistor. The method comprises forming a shallow-trench isolation region in a semiconductor substrate of a first conductive type; forming a lower gate electrode on the semiconductor substrate; forming an ion-implantation blocking layer on the lower gate electrode; forming an upper gate electrode on the ion-implantation blocking layer; and performing an ion-implantation step to form a diffusion area of a second conductive type in the semiconductor substrate adjacent the gate electrode.

In an embodiment of the present invention, an amorphous silicon layer preferably forms a top portion of the gate electrode. In another embodiment of the present invention, an amorphous silicon layer forms an intermediate portion of the gate electrode, which comprises a lower gate electrode and an upper gate electrode, wherein the intermediate amorphous silicon layer is interposed between the lower gate electrode and the upper gate electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principle of the invention. In the drawings:

FIG. 1 is a plan view of a CMOS image sensor of the related art having three transistors;

FIG. 2 is a plan view of a CMOS image sensor of the related art having four transistors;

FIG. 3 is a cross-sectional view cut along line A-A′ or B-B′, illustrating the CMOS image sensor of FIG. 1 or FIG. 2;

FIG. 4 is a cross-sectional view cut along line A-A′ or B-B′, illustrating a process step for fabricating the CMOS image sensor of FIG. 1 or FIG. 2;

FIG. 5 is a cross-sectional view of a CMOS image sensor according to an embodiment of the present invention, illustrating an ion-implantation step for forming a deep N⁻ region; and

FIG. 6 is a cross-sectional view of a CMOS image sensor according to another embodiment of the present invention, illustrating an ion-implantation step for forming a deep N⁻ region.

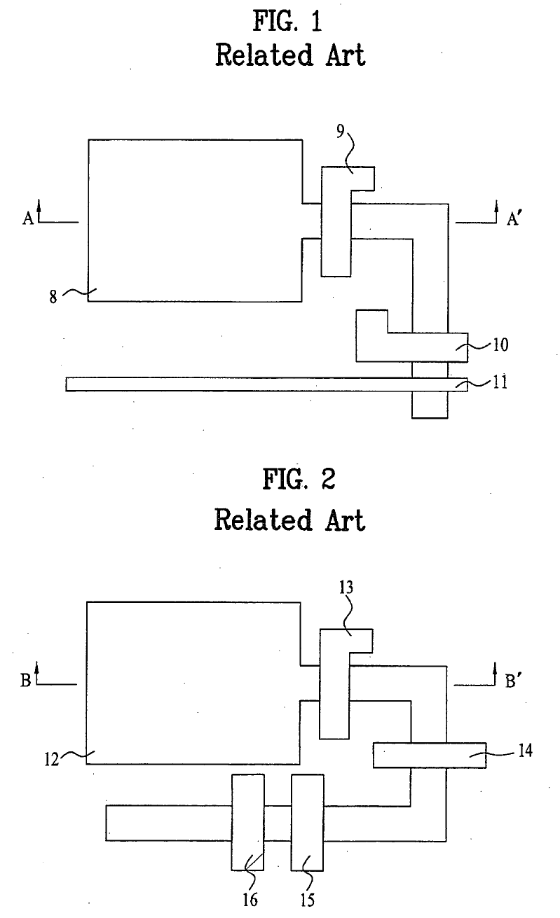

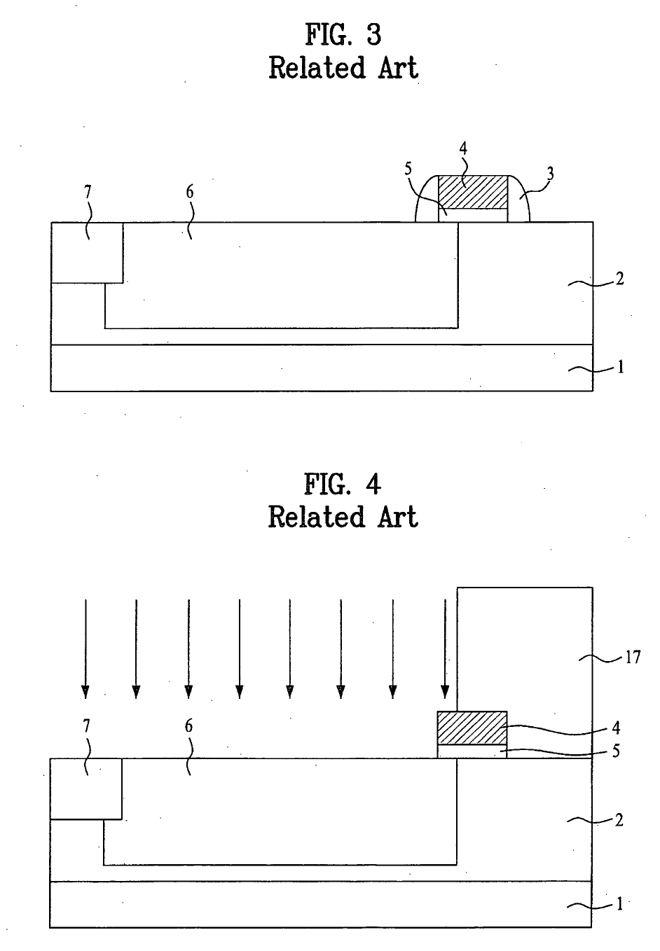

### DETAILED DESCRIPTION OF THE INVENTION

Reference will now be made in detail to the embodiments of the present invention, examples of which are illustrated in the accompanying drawings. Wherever possible, like reference designations will be used throughout the drawings to refer to the same or similar parts.

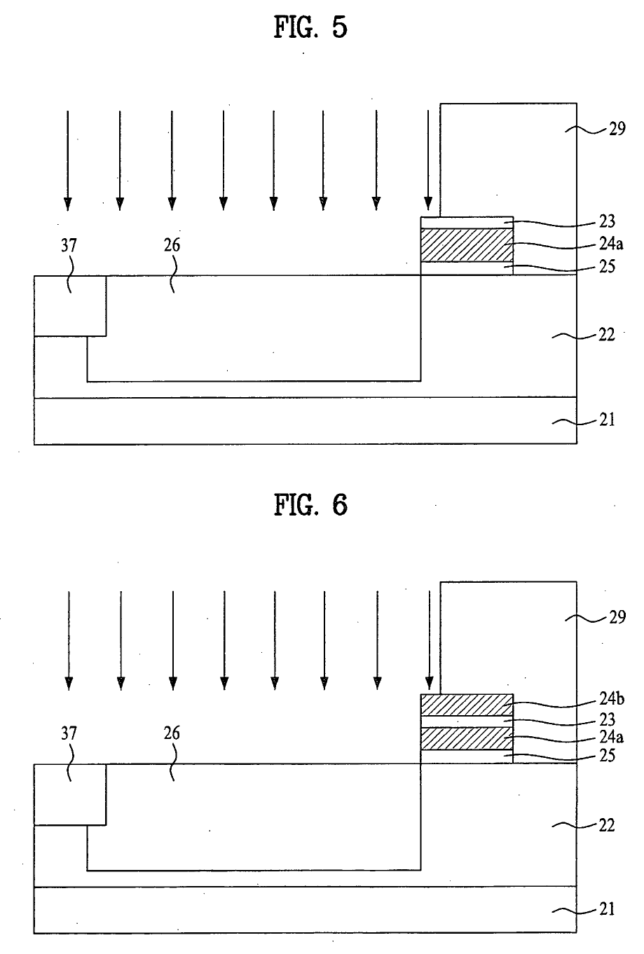

Referring to FIG. 5, illustrating a CMOS image sensor according to an embodiment of the present invention, a reset transistor or a transfer transistor is formed in a semiconductor substrate 21 heavily doped with P-type impurity ions. FIG. 5 is a cross-section of a reset transistor or a transfer transistor. The reset transistor or the transfer transistor each include a P-type epitaxial layer 22 formed on the semiconductor substrate 21, a shallow-trench isolation region 37, a deep N⁻ region 26 formed as a diffusion area in a predetermined surface region of the P-type epitaxial layer 22, a gate oxide layer 25, and a gate electrode 24a of polysilicon sequentially formed on the epitaxial layer 22 to be disposed adjacent the deep N⁻ region 26. The shallow-trench isolation region 37, which provides isolation between fields, is essentially a trench filled with an insulating material.

The transistor of the CMOS image sensor of the present invention is a reset transistor or transfer transistor and, according to an embodiment, includes an amorphous silicon layer 23 formed at the top of the gate electrode 24a. Alternatively, the amorphous silicon layer 23 of the present invention may be formed at the bottom of the gate electrode 24a.

The amorphous silicon layer 23 functions as an ion-implantation blocking layer. That is, the amorphous silicon layer 23 prevents the deep N⁻ region 26 from being formed in a channel region below the gate electrode 24a, since the amorphous silicon layer is capable of withstanding higher energy levels, and therefore more severe atomic collisions, during an ion-implantation step such as that for forming the deep N⁻ region 26. Specifically, the amorphous silicon layer 23 exhibits higher atomic collision characteristics than a polysilicon layer of gate electrode 24a. The thickness of the amorphous silicon layer 23 may vary according to the intended energy level of the ion implantation. Also, the amorphous silicon layer 23 is formed at a lower temperature than that at which the polysilicon layer is formed.

A photoresist pattern 29 is formed on the amorphous silicon layer 23 and serves, together with the gate electrode 24a, as an ion-implantation mask for forming the deep N⁻ region 26, which is formed by lightly doping the P-type epitaxial layer 22 with impurities. Here, the deep N⁻ region 26 is typically formed before the formation of spacers (not shown) on the gate sidewalls.

Referring to FIG. 6, illustrating a CMOS image sensor according to another embodiment of the present invention, the gate electrode of a reset transistor or a transfer transistor comprises a lower gate electrode 24a, an upper gate electrode 24b, and an amorphous silicon layer 23 as an ion-implantation blocking layer interposed between the lower gate electrode 24a and the upper gate electrode 24b. That is, the lower gate electrode 24a is formed on the gate oxide layer 25 and the amorphous silicon layer 23 is formed on the lower gate electrode 24a. The upper gate electrode 24b is formed on the intermediately positioned amorphous silicon layer. In this case, the photoresist pattern 29 is formed on the upper gate electrode 24b.

By adopting the CMOS image sensor according to the present invention, the leakage current of the reset transistor or the transfer transistor can be minimized and uniform electrical characteristics per pixel can be maintained, thereby improving image characteristics. Furthermore, where the amorphous silicon layer is formed on the upper side of the gate electrode, there is no need to prepare an amorphous upper side of the gate electrode, thereby simplifying the fabrication process.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their variations.

What is claimed is:

1. A CMOS image sensor having a transistor comprising:
a semiconductor substrate;
a gate electrode of the transistor formed on said semiconductor substrate; and
an ion-implantation blocking layer formed as part of said gate electrode.

2. The CMOS image sensor of claim 1, wherein said ion-implantation blocking layer is formed at a top portion of said gate electrode.

3. The CMOS image sensor of claim 2, wherein said ion-implantation blocking layer forms an upper surface of said gate electrode.

4. The CMOS image sensor of claim 1, wherein said ion-implantation blocking layer is formed at a bottom portion of said gate electrode.

5. The CMOS image sensor of claim 1, wherein said ion-implantation blocking layer is formed at an intermediate portion of said gate electrode.

6. The CMOS image sensor of claim 5, wherein said gate electrode comprises a lower gate electrode and an upper gate electrode, wherein an amorphous silicon layer is interposed between said lower gate electrode and said upper gate electrode.

7. The CMOS image sensor of claim 1, wherein said ion-implantation blocking layer is an amorphous silicon layer.

8. The CMOS image sensor of claim 7, wherein said semiconductor substrate is a first conductive type and said amorphous silicon layer has a thickness varying according to an intended energy level of an ion implantation for forming a diffusion area of a second conductive type in said semiconductor substrate adjacent said gate electrode.

9. The CMOS image sensor of claim 7, wherein said gate electrode is formed by patterning a polysilicon layer.

10. The CMOS image sensor of claim 9, wherein said amorphous silicon layer exhibits higher atomic collision characteristics than the polysilicon layer.

11. The CMOS image sensor of claim 9, wherein said amorphous silicon layer is formed at a lower temperature than that at which the polysilicon layer is formed.

12. The CMOS image sensor of claim 1, further comprising:
an epitaxial layer formed by lightly doping said semiconductor substrate with impurities of a first conductivity, wherein said semiconductor substrate is heavily doped with impurities of the first conductivity.

13. The CMOS image sensor of claim 1, further comprising:
a shallow-trench isolation region, formed in said semiconductor substrate as a trench filled with an insulating material, for providing isolation between fields.

14. The CMOS image sensor of claim 1, wherein the transistor is one of a reset transistor and a transfer transistor.

15. A method for fabricating a CMOS image sensor having a transistor, comprising:
forming a shallow-trench isolation region in a semiconductor substrate of a first conductive type;
forming a gate electrode on the semiconductor substrate;
forming an ion-implantation blocking layer as part of the gate electrode; and
performing an ion-implantation step to form a diffusion area of a second conductive type in the semiconductor substrate adjacent the gate electrode.

16. A method for fabricating a CMOS image sensor having a transistor, comprising:
forming a shallow-trench isolation region in a semiconductor substrate of a first conductive type;
forming a lower gate electrode on the semiconductor substrate;
forming an ion-implantation blocking layer on the lower gate electrode;
forming an upper gate electrode on the ion-implantation blocking layer; and
performing an ion-implantation step to form a diffusion area of a second conductive type in the semiconductor substrate adjacent the gate electrode.
